(19) United States
(12) Patent Application Publication
(10) Pub. No.: US 2012/0306859 A1
(43) Pub. Date: Dec. 6, 2012

(54) TERMINAL FOR SUPPORTING MULTI-DISPLAY MODE AND DRIVING METHOD THEREOF

(75) Inventors: Sang Yong EOM, Suwon-si (KR); Dong Sub KIM, Suwon-si (KR)

(73) Assignee: SAMSUNG ELECTRONICS CO. LTD., Suwon-si (KR)

(21) Appl. No.: 13/426,993

(22) Filed: Mar. 22, 2012

(30) Foreign Application Priority Data
May 30, 2011 (KR) 10-2011-0051310

(51) Int. Cl. G06T 15/00; G09G 5/10; H05K 7/00

(52) U.S. Cl. 345/419; 361/679.01; 345/690

(57) ABSTRACT

A terminal for supporting multi-display modes and a driving method thereof are provided. The method for driving a terminal, having first and second emitters for supporting multi-display modes, includes confirming a preset value of currently set multi-display modes, controlling emissions of the first and second emitters according to the preset value of the multi-display modes, and outputting a screen on a display unit through the first and second controlled emitters.

### PRIORITY

This application claims the benefit under 35 U.S.C. §119(a) of a Korean patent application filed on May 30, 2011 in the Korean Intellectual Property Office and assigned Serial No. 10-2011-0051310, the entire disclosure of which is hereby incorporated by reference.

### BACKGROUND OF THE INVENTION

1. Field of the Invention

The present invention relates to control of a terminal. More particularly, the present invention relates to a terminal for supporting multi-display modes capable of supporting 2D and 3D multi-display modes using one panel, and a driving method thereof.

2. Description of the Related Art

Several methods exist to support a 3D display mode. In one method, a user views different near and far scenes in each eye. Two different deflected images are displayed on one screen, and the user implements 3D images using a deflection filter for each eyes. Methods for implementing 3D images include an auto-stereoscopic display method or 3D display method using an aperture or slit array associated with a 2D display so as to display 3D images. The basis of the auto-stereoscopic 3D display method is a principle that a user views different parts of a 2D image in each eye where the user views a 2D image through a slit array spaced apart from a screen by a predetermined distance. When a suitable image is rendered and displayed on a 2D display, the user may watch a different perspective image without using filters in respective eyes. Similarly, a 3D display scheme according to a binocular parallax scheme may be used. The auto-stereoscopic scheme and the binocular parallax scheme may support a glasses-free 3D scheme.

A controller of a light source in the foregoing 3D display scheme also performs control of the light source in a 2D display scheme. Accordingly, a display device of the related art provides an image of a 3D display scheme to a user. However, because control of the light source is not performed suitable, an inappropriate image floating between a 2D image and a 3D image may be provided to the user. Accordingly, there is a need for a method for suitably providing a 3D image to the user.

### SUMMARY OF THE INVENTION

Aspects of the present invention are to address at least the above-mentioned problems and/or disadvantages and to provide at least the advantages described below. Accordingly, an aspect of the present invention is to provide a terminal for supporting multiple display modes to suitably control an optical source of a terminal so as to support a 3D display of a glasses-free scheme and a driving method thereof.

In accordance with an aspect of the present invention, a terminal for supporting multi-display modes is provided. The terminal includes a display unit including a first emitter and a second emitter, a controller for controlling emissions of the first emitter and the second emitter according to a set multi-display mode, and an emission driver for controlling power supply of the first emitter and the second emitter under control of the controller.

In accordance with another aspect of the present invention, a method for driving a terminal including first and second emitters for supporting multi-display modes is provided. The method includes confirming a preset value of currently set multi-display modes, controlling emissions of the first and second emitters according to the preset value of the multi-display modes, and outputting a screen on a display unit through the first and second controlled emitters.

In accordance with another aspect of the present invention, a terminal supporting a two-dimensional (2D) display mode and a three-dimensional (3D) display mode is provided. The terminal includes a display unit including a first emitter and a second emitter, a controller for controlling the first emitter and the second emitter to both emit light or not emit light simultaneously when the display unit operates in 2D display mode, and for controlling the first emitter and the second emitter to emit light alternately when the display unit operates in the 3D display mode, and an emission driver for controlling power supply of the first emitter and the second emitter according to the control of the controller.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a perspective view schematically illustrating a configuration of a part of an appearance of a terminal according to an exemplary embodiment of the present invention;

FIG. 2 is a block diagram illustrating a configuration of a terminal according to an exemplary embodiment of the present invention;

FIG. 3 is a view illustrating a power supply state required to drive a 2D mode and a 3D mode modes according to an exemplary embodiment of the present invention;

FIG. 4 is a waveform diagram illustrating signals supplied to drive emitters according to an exemplary embodiment of the present invention; and

FIG. 5 is a flowchart illustrating a driving method of a terminal supporting multi-display modes according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding, but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but are merely used by the inventor to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

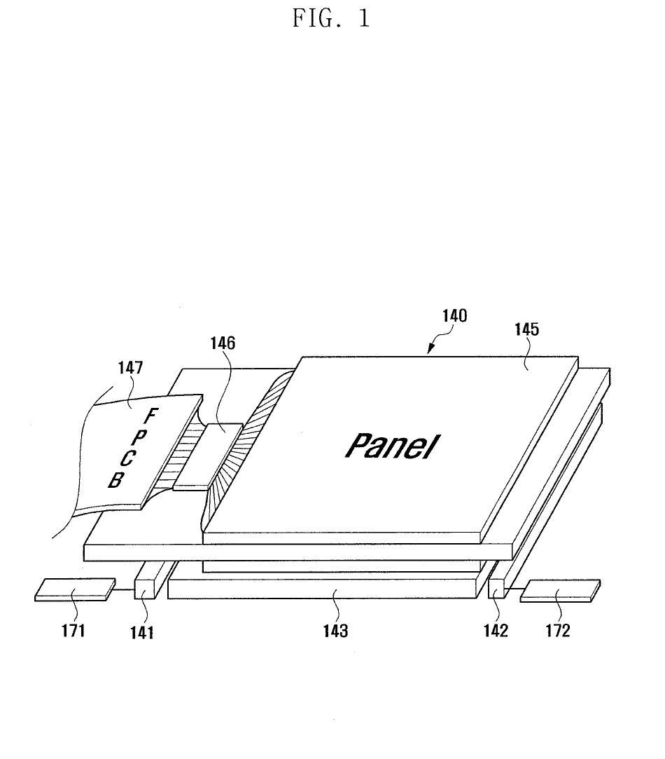

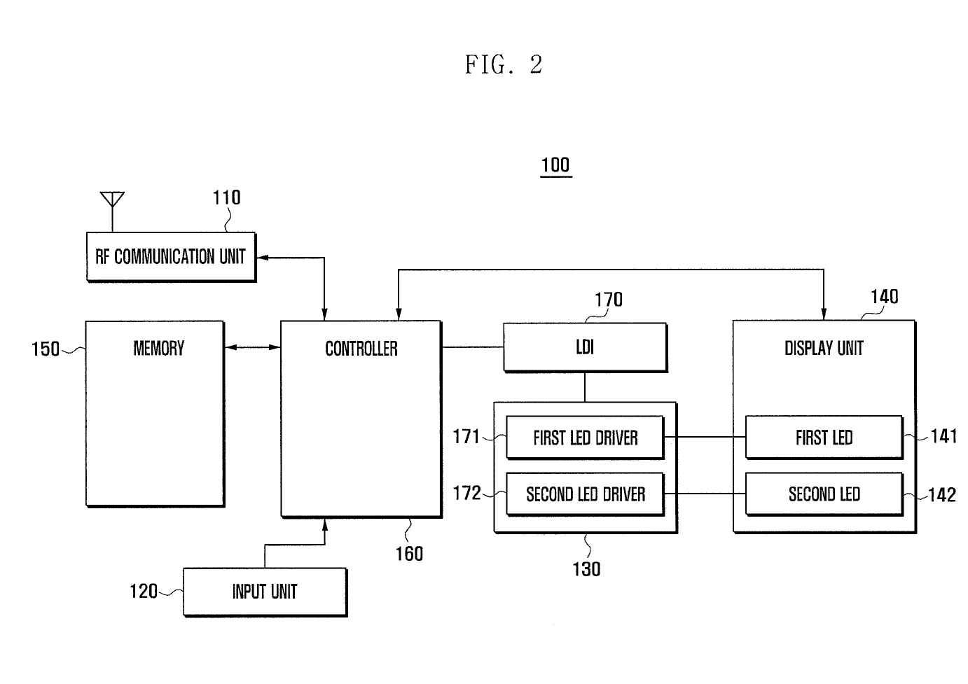

FIG. 1 is a perspective view schematically illustrating a configuration of a part of an appearance of a terminal according to an exemplary embodiment of the present invention. FIG. 2 is a block diagram illustrating a configuration of a terminal according to an exemplary embodiment of the present invention.

Referring to FIGS. 1 and 2, a terminal 100 according to an exemplary embodiment of the present invention may include a Radio Frequency (RF) communication unit 110, an input unit 120, a display unit 140, a memory 150, a controller 160, an LCD Driver Integrated circuit (LDI) 170, and an emission driver, for example, a Light Emitting Diode (LED) driver 130. The display unit 140 may include a first emitter and a second emitter. For example, as shown in FIG. 1, the first emitter and the second emitter may be a first LED 141 and a second LED 142.

The emission driver may include a first emission driver for controlling power supply of the first emitter and a second emission driver for controlling power supply of the second emitter. The emitters are shown as an LED, but other types of emitters may also be employed. The emission driver may be an LED driver 130. For example, the first emission driver may be a first LED driver 171 for controlling power supply of the first LED 141, and the second emission driver may be a second LED driver 130 for driving the second LED 142. Hereinafter, the emitters and the emission driver are described as an LED. During a 3D mode operation, the first LED driver 171 and the second LED driver 172 control so that the first LED 141 and the second LED 142 are alternately turned on and off During a 2D operation, the first LED driver 171 and the second LED driver 172 may control so that the first LED 141 and the second LED 142 are simultaneously turned on and off. Accordingly, the terminal 100 may display a distinct three-dimensional image during a 3D mode operation.

The RF communication unit 110 forms a communication channel for voice calls, a communication channel for videophone calls, and a communication channel for transmitting data such as images or messages under the control of the controller 160. The RF communication unit 110 may receive data through the formed channels, and output the received data to the display unit 140 under the control of the controller 160. Data received by the RF communication unit 110 may be output to the display unit 140 in a 2D mode or a 3D mode according to selection of the user. A screen necessary for an operation of the RF communication unit 110 may be displayed in one of several multi-modes according to the selection of the user.

The input unit 120 includes a plurality of input keys and function keys for receiving input of numeral or character information and for setting various functions. The function keys may include arrow keys, side keys, and hot keys set so that a certain function is performed. The input unit 120 creates and transfers a key signal associated with user setting and function control of the terminal 100 to the controller 160. The input unit 120 may create and transfer an input signal for selecting multi-modes of an image output through the display unit 140 to the controller 160 according to user control. The input unit 120 may create an input signal for setting the 2D and an input for setting the 3D according to the selection of the user.

The LED driver 130 includes a first LED driver 171 and a second LED driver 171 for controlling the first LED 141 and the second LED 142 included in the display unit 140, respectively. When the display unit 140 is set in the 2D mode, the first LED driver 171 and the second LED driver 172 may perform a control operation to simultaneously turn on and turn off the first LED 141 and the second LED 142 based on a first power value, respectively. When the display unit 140 is set in the 3D mode, the first LED driver 171 and the second LED driver 172 may perform a control operation to alternately turn on and turn off the first LED 141 and the second LED 142 based on the second power value, respectively. In this case, the second power value may be set higher than the first power value.

The display unit 140 displays information input by the user and information provided to the user as well as various menus. The display unit 140 may provide various screens, such as an idle screen, a menu screen, a message creation screen, and a call screen according to utilization of the terminal 100. The display unit 140 may be configured by a Liquid Crystal Display (LCD) or an Organic Light Emitted Diode (OLED). The display unit 140 may be disposed at an upper part or a lower part of a touch panel and may act as a touch screen.

As shown in FIG. 1, the display unit 140 may include a display panel 145, a panel driver 146, a Flexible Printed Circuit Board (FPCB) 147, and a backlight unit. The display panel 145 may be configured by an LCD. The panel driver 146 is disposed at a side of the display panel 145, and provides a signal necessary for driving the display panel 145. The panel driver 146 may connect with the controller 160 through the FPCB 147. The panel driver 146 receives data to be output to the display panel 145 from the controller 160 through the FPCB 147, and transfers the received data to a corresponding display panel. The panel driver 146 receives and transfers distinct signals from the controller 160 to the LED driver 130 according to setting the 2D mode or the 3D mode.

When setting the 2D mode, the panel driver 146 may transfer the same signal, namely, a signal for controlling so that the first LED 141 and the second LED 142 are simultaneously turned on and turned off to the first LED driver 171 and the second LED driver 172, respectively. The panel driver 146 may transfer an alternate signal, namely, a signal controlling such that the second LED 142 is turned off while the first LED 141 is turned on and the first LED 141 is turned off while the second LED 142 is turned on to the first LED driver 171 and the second LED driver 172, respectively.

In this case, the panel driver 146 may transfer a control signal to the first LED driver 171 and the second LED driver 172 such that a relatively higher power is supplied in a 2D mode than that in a 3D mode.

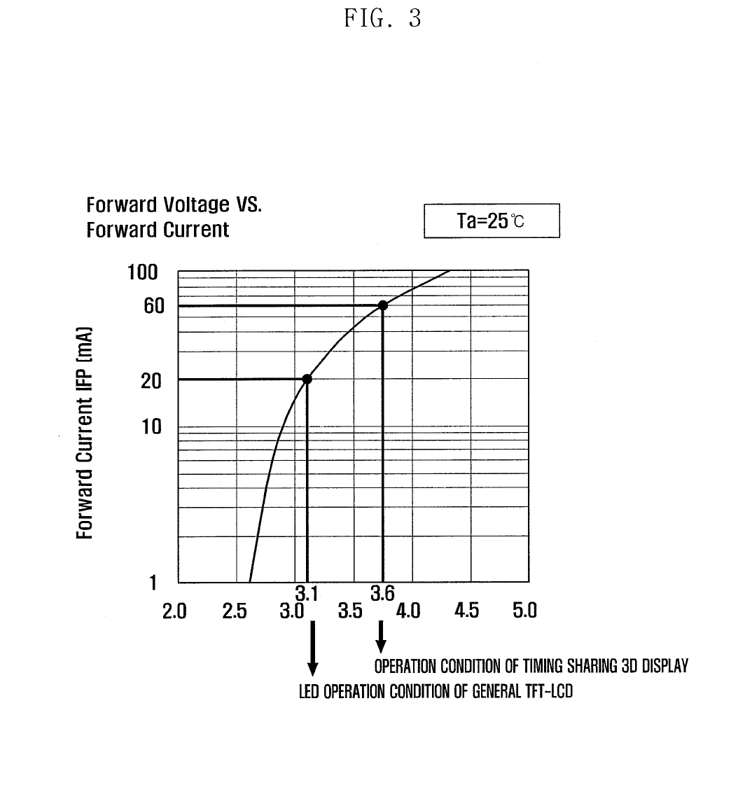

FIG. 3 is a view illustrating a power supply state required to drive a 2D mode and a 3D mode modes according to an exemplary embodiment of the present invention.

Referring to FIG. 3, the supply of a relatively higher power, for example, higher current to drive a display panel 145 in a 3D mode may be needed as compared to that in a 2D mode. Because partial light is output through a slit array on the display panel 145 in a deflective scheme in a 3D mode and the first LED 141 and the second LED 142 are alternately operated, if the same LED light source as that in a 2D mode is provided, the screen may be too dark. As a result, a relatively higher current in a 3D mode is supplied in comparison with that in a 2D mode, so that luminance of an LED light source may be increased to maintain screen brightness at a predetermined reference value.

The backlight unit is arranged at a lower part of the display unit 145 and transmits light to a rear of the display panel 145. The backlight unit may include a light guide plate 143, the first LED 141, and the second LED 142. The first LED 141 and the second LED 142 may be disposed at both sides of the light guide plate 143, and provide light to the light guide plate 143. The backlight unit may further include a prism sheet disposed between the light guide plate 143 and the display panel 145, and a reflection plate disposed at a rear surface of the light guide plate 143. The backlight unit may include a lamp housing structure enclosing the first LED 141 and the second LED 142. FIG. 1 schematically illustrates only structural elements associated with control of a light source, and the backlight unit may include the foregoing various structural elements.

The first LED 141 and the second LED 142 may be turned on or off according to a signal provided from the LED driver 130, and may change the size of an irradiated light source according to the provided signal. The first LED 141 and the second LED 142 are disposed at both sides of the light guide plate 143 and provide a light source from a side of the light guide plate 143 to an inner side of the light guide plate 143.

The light guide plate 143 vertically generates light transmitted from the first LED 141 and the second LED 142 and guides the light to the display panel 145. The light guide plate 143 may include both of a pattern generating light transmitted from the first LED 141 and a pattern generating light from the second LED 142, or be provided with two light guide plate structures. When one light guide plate 143 is provided, a pattern generating light of a first LED 141 entering a first direction and a pattern generating light of a second LED 142 entering a second direction may be provided inside the light guide plate 143. When the light guide plate 143 is configured by two light guide plate structures, respective light guide plates generate light transmitted from respective LEDs. In this case, two light guide plates may be stacked and the first LED 141 and the second LED 142 are displayed at different heights and irradiate light to respective light guide plates.

The memory 150 may store various data to be output on the display unit 140 as well as application programs necessary for a function operation according to an exemplary embodiment of the present invention. When the display unit 140 is configured by a touch screen, the memory 150 may store information key maps or menu maps for an operation of the touch screen, and information with respect to a touch lock part release region. In this case, the key maps or the menu maps may become various forms. The memory 150 may store a multi-mode support program according to an exemplary embodiment of the present invention. The multi-mode support program stores routines for identifying user settings and controlling an image output mode of the display panel 145 according to a set state. The multi-mode support program may include a routine for supporting output of 2D images or 3D images with defaults, a routine for controlling a slit array of the display panel 145 according to the set mode, and a routine for controlling an LED driver 130 of the display panel 145.

The routine controlling the LED driver 130 may include a sub-routine confirming a currently set mode, a sub-routine controlling such that the first LED 141 and the second LED 142 are simultaneously turned on and off, and a sub-routine controlling such that the first LED 141 and the second LED 142 are alternately turned on and off with a power supply amount of a preset value according the set mode. In this case, the preset value may be set greater than a power supply amount provided in the 2D mode.

The LDI 170 supplies power necessary for the LED driver 130. Although it is shown in the form of power supply for controlling light source of the present invention, the LDI 170 controls supplied power from a power supply unit of the terminal 100 to supply power necessary for driving the display panel 145.

The controller 160 controls power supply to respective structural elements of the terminal 100 to perform an initializing procedure of the elements. The controller 160 may control and transfer signals necessary for controlling a light source to the display unit 140. The controller 160 may determine generation of an input signal with respect to setting a 2D mode or a 3D mode from an input unit 120 or a display unit 140 of a touch screen function or determine a default mode value.

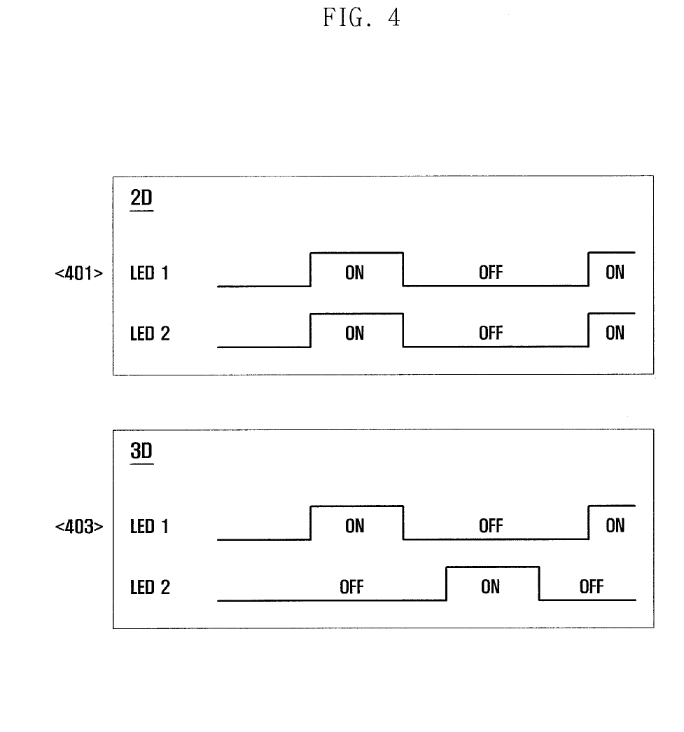

FIG. 4 is a waveform diagram illustrating signals supplied to drive emitters according to an exemplary embodiment of the present invention.

Referring to FIG. 4, when the 2D mode is set, the controller 160 may control an LED driver 130 so that a signal shown in a waveform diagram 401 is supplied to the first LED 141 and a second LED 142. The waveform diagram 401 illustrates a power timing of the signal supplied to the first LED 141 and the second LED 142 in setting a 2D mode. The controller 160 synchronizes power supply timing of the second LED 143 with that of the first LED 141 to control so that the first LED 141 and the second LED 143 are turned on and off during the same time period. The time intervals in a power supply timing of the first LED 141 and the second LED 143 may be changed according to driving the display panel 145. When the display unit 140 is driven in the 2D mode, the first LED 141 and the second LED 142 may be continuously turned on for a predetermined time without turning off.

When the display unit 140 is changed to a sleep mode while the display unit 140 is driven in a 2D mode, light of the first LED 141 and the second LED 142 supplying the light to the display unit 140 may be turned off with the same time period. Accordingly, it will be understood that the waveform diagram 401 illustrates that the first LED 141 and the second LED 142 are turned on or turned off during the same time period according to output of data of the display unit 140. When the 3D mode is set, the controller 160 controls the LED driver 130 to supply signals shown in a waveform diagram of FIG. 4 to the first LED 141 and the second LED 143.

A waveform diagram 403 illustrates power timing supplied to the first LED 141 and the second LED 142 in setting a 3D mode. The first LED 141 is turned on during the same time interval in which the second LED 142 is turned off Accordingly, light transmitted from the first LED 141 and that transmitted from the second LED 142 may have a predetermined time difference. The first LED 141 and the second LED 142 are turned on and off with a predetermined time interval such that the terminal 100 may clearly implement glasses-free 3D images by charging light emitted from the display panel 145 through a slit array.

Amplitude of a waveform shown in the waveform diagram 403, namely, a power supply amount may be set relatively higher than amplitude of a waveform shown in the waveform diagram 401. In this case, a predetermined guard region may be provided at turning on and off change boundary regions of the first LED 141 and the second LED 142. The controller 160 may control the first LED 141 and the second LED 142 so that the second LED may be turned on a predetermined time interval after the first LED 141 is turned on.

The time interval in a turning on or off boundary region of the first LED 141 and the second LED 142 may be changed to a time interval between timing irradiated from light through the first LED 141 and that irradiated from light through the second LED 142. As a result, a time interval between screen output through the first LED 141 and that through the second LED 142 is provided so that a controller 160 of the present invention may improve image recognition in a glasses-free 3D image scheme. A time interval between turning on and turning off the first LED 141 and the second LED 142 may be controlled according to reaction speed of the first LED 141 and the second LED 142 and the size of the display unit 140.

As illustrated previously, a terminal supporting a multi-mode display mode according to an exemplary embodiment of the present invention differently operate the first LED 141 and the second LED 142 disposed at different locations on the display unit 140 at 2D mode operation time and a 3D mode operation time to more clearly implement images according to respective modes.

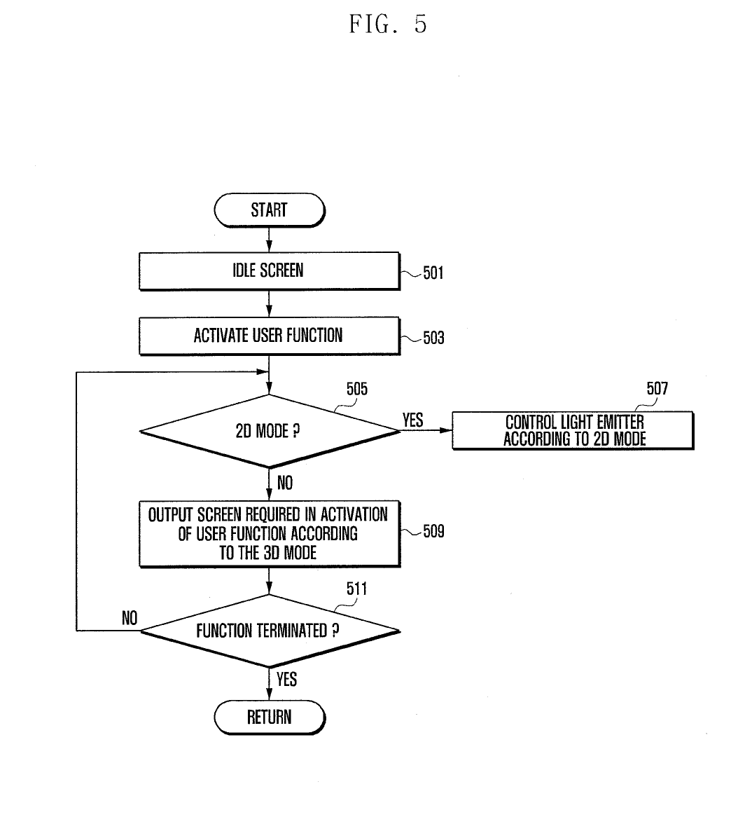

The foregoing exemplary embodiments have illustrated an appearance of a terminal supporting a multi-display mode and functions of respective structural elements of the present invention. Hereinafter, a method for driving the terminal supporting the multi-display mode will be described in detail with reference to FIG. 5.

FIG. 5 is a flowchart illustrating a driving method of a terminal supporting a multi-display mode according to an exemplary embodiment of the present invention.

Referring to FIG. 5, the user may supply power to a terminal 100 to operate the terminal 100. A battery or a charger of the terminal 100 may be connected and an input signal for supplying power may be created. When power is supplied, the terminal 100 creates the power necessary for an operation of respective structural elements using the supplied power, and initializes the respective structural elements using the created power. If the initialization is terminated, the terminal 100 may control the display unit 140 to output an idle screen according to preset schedule information in step 501.

The terminal 100 may activate a user function according to an input signal created by the input unit 120 and an input signal created by a display unit 140 of a touch screen function in step 503. The controller 160 may determine whether a display unit 140 is set in a 2D mode in step 505. Setting the 2D mode may be determined according to activation of the user function or user setting. A certain user function may be automatically set to a 3D mode or a 2D mode. If the user creates an input signal for activating a corresponding user function, the controller 160 may obtain a multi-display mode setting value of the corresponding user function to determine in which mode the user function is performed.

Although the user function is automatically set in the 2D mode or the 3D mode, the user may create an input signal for instructing change to another mode, namely, to the 3D mode or the 2D mode. Accordingly, the controller 160 may determine the mode based on a multi-display mode setting value according to generation of an input signal corresponding to user instruction. Accordingly, it will be understood that step 505 is a step of determining whether a user function set in at least one of a 2D mode or a 3D mode.

If an operation of the display unit 140 is set in a 2D mode at step 505, the controller 160 may activate the user function and output a required screen according to the 2D mode. To do this, the controller 160 may control an emitter according to the 2D mode in step 507. The controller 160 may control the LED driver 130 so that a first LED 141 and a second LED 142 provided at the display unit 140 are simultaneously turned on or turned off. By transferring a signal for driving the first LED 141 and the second LED 142 to the panel driver 146, the panel driver 146 may transfer a control signal for driving the first LED 141 and the second LED 142 to the LED driver 130. The first LED 141 and the second LED 142 transmit light to a light guide plate and inputs simultaneously transmitted light from the first LED 141 and the second LED 142 toward the display panel 145 through the light guide plate.

When an operation of the display unit 140 is not set in the 2D mode, namely, is set in the 3D mode or an input signal for setting a 3D mode is created, the controller 160 may control such that a screen required in activation of the user function is output according to the 3D mode in step 509. The controller 160 may control the LED driver 130 such that turning-on time intervals of the first LED 141 and the second LED 142 are alternately generated. For example, while the first LED 141 is turned-on during a first time interval, the second LED 142 may be turned off. While the first LED 141 is turned off during a second time interval, the second LED 142 may be turned on. A time interval corresponding to a third time interval may be provided between a first time interval and a second time interval. During the third time interval, the first LED 141 and the second LED 142 may all be turned off. The third time interval may be arranged between turning-on and turning-off time points of the first LED 141 and the second LED 142.

Because the second LED 142 is turned off while the first LED 141 is turned off, light emitted from the first LED 141 drives the display panel 145. Accordingly, the illuminanace may be deteriorated in comparison with when the first LED 141 and the second LED 142 are simultaneously turned on. In order to maintain this, the controller 160 may control such that the magnitude of power supplied to drive the first LED 141 and the second LED 142 in the 3D mode is greater than that in the 2D mode while the first LED 141 and the second LED 142 are operated in the 3D mode. Accordingly, in the method for driving a terminal according to an exemplary embodiment of the present invention, abnormal deterioration of illuminance is prevented while implementing the 3D mode to make the brightness of a screen being a preset value and to implement an image according to the 3D mode.

The controller 160 may determine whether an activated function is terminated in step 511. The controller 160 may determine whether an input signal or an event for terminating a corresponding user function is generated. When the input signal for terminating the user function is not generated, that is, when a currently activated user function is maintained, the process returns to step 505 and repeats the foregoing procedures. The controller 160 may control a light emitter of the display unit 140 for supporting a mode changed according to whether a previously set multi-display mode is changed. Upon operation of a 3D mode, the controller 160 may control a glasses-free 3D scheme of the display unit 140. The foregoing exemplary embodiments have illustrated the glasses-free 3D scheme using a slit array by way of example. However, exemplary embodiments of the present invention are not limited thereto. A control technology of a light source according to an exemplary embodiment of the present invention may be equally applicable to a 3D scheme based on a parallax barrier or a 3D scheme based on a lenticular lens among auto-stereoscopic 3D schemes.

The terminal 100 may further include various additional modules. When the terminal 100 is a communication terminal, the terminal 100 may include elements that are not shown, such as a near distance communication module for near distance communication, an interface for exchanging data in a wired communication scheme or a wireless communication scheme of the mobile terminal 100, an Internet communication module for communicating with an Internet to perform an Internet function, and a digital broadcasting module for receiving and broadcasting digital broadcastings. Since the structural elements may be variously changed according to convergence trend of a digital device, these elements are not shown. However, the terminal 100 may include structural elements equivalent to the foregoing structural elements. Further, the terminal 100 may be substituted by specific constructions in the foregoing arrangements according to the provided form or another structure. This can be easily understood by those skilled in the present art.

The terminal 100 according to an exemplary embodiment of the present invention may be any of various types of devices having a display unit capable of implementing a 3D mode. For example, the terminal 100 may include an information communication device and a multimedia device such as a Portable Multimedia Player (PMP), a digital broadcasting player, a Personal Digital Assistant (PDA), a music player (e.g., MP3 player), a portable game terminal, a Smart Phone, a notebook computer, and a handheld PC as well as various mobile communication terminals corresponding to various communication systems.

As illustrated previously, in a terminal supporting a multi-display mode according to exemplary embodiments of the present invention, the terminal may suitably perform control of a light source in a 2D image and a 3D image so that a user can watch images having distinct differences between 2D and 3D images.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A terminal for supporting multi-display modes, the terminal comprising:
a display unit including a first emitter and a second emitter;
a controller for controlling emissions of the first emitter and the second emitter according to a set multi-display mode; and
an emission driver for controlling power supply of the first emitter and the second emitter under control of the controller.

2. The terminal of claim 1, wherein the display unit comprises:
a light guide plate;
a display panel disposed at an upper part of the light guide plate; and
a panel driver for driving the display panel,
wherein the first emitter is disposed at a side of the light guide plate, and the second emitter is disposed at another side of the light guide plate.

3. The terminal of claim 2, wherein the controller transfers a control signal for controlling the first emitter and the second emitter to the panel driver.

4. The terminal of claim 3, wherein the emission driver comprises:
a first emission driver for controlling power supply of the first emitter; and
a second emission driver for controlling power supply of the second emitter.

5. The terminal of claim 4, wherein the panel driver transfers a control signal for controlling the first emitter to the first emission driver, and transfers a control signal for controlling the second emitter to the second emission driver.

6. The terminal of claim 1, wherein the first emitter and the second emitter are simultaneously turned on and off while the terminal is operating in a two-dimensional mode of the multi-display modes.

7. The terminal of claim 1, wherein the first emitter and the second emitter are alternately turned on and off while the terminal is operating in a three-dimensional mode of the multi-display modes.

8. The terminal of claim 7, wherein the display unit implements a three-dimensional image according to a three-dimensional mode based on time share.

9. The terminal of claim 7, wherein the second emitter is turned off while the first emitter is turned on during a first time interval, and the second emitter is turned on while the first emitter is turned off during a second time interval.

10. The terminal of claim 9, wherein the first and second emitters are simultaneously turned off during a third time interval between the first and second time intervals.

11. The terminal of claim 1, wherein the emission driver sets and supplies power to the first and second emitters to support a three-dimensional mode of the multi-display modes to be greater than the power set and supplied to support a two-dimensional mode.

12. A method for driving a terminal including first and second emitters for supporting multi-display modes, the method comprising:
confirming a preset value of currently set multi-display modes;
controlling emissions of the first and second emitters according to the preset value of the multi-display modes; and
outputting a screen on a display unit through the first and second controlled emitters.

13. The method of claim 12, further comprising:
transferring a control signal for controlling the first and second emitters to a panel driver for driving a display panel of the display unit;
transferring the control signal to an emission driver provided for power supply of the first and second emitters by the panel driver; and
supplying power to the first and second emitters according to the control signal.

14. The method of claim 12, wherein the controlling of the emissions of the first and second emitters comprises performing a control operation to simultaneously turn on and off the first and second emitters while the terminal is operating in a two-dimensional mode of the multi-display modes.

15. The method of claim 12, wherein the controlling of the emissions of the first and second emitters comprises performing a control operation to alternately turn on and off the first and second emitters while the terminal is operating in a three-dimensional mode of the multi-display modes.

16. The method of claim 15, wherein an image implemented by the display unit is a three-dimensional image according to a three-dimensional mode based on time share.

17. The method of claim 15, wherein the performing of the control operation comprises:
during a first time interval, turning off the second emitter and turning on the first emitter; and
during a second time interval, turning on the second emitter and turning off the first emitter.

18. The method of claim 17, wherein the performing of the control operation comprises simultaneously turning off the first and second emitters during a third time interval between the first and second time intervals.

19. The method of claim 12, wherein the performing of the control operation comprises setting and supplying power to the first and second emitters to support a three-dimensional mode of the multi-display modes to be greater than the power set and supplied to support a two-dimensional mode.

20. A terminal supporting a two-dimensional (2D) display mode and a three-dimensional (3D) display mode, the terminal comprising:
a display unit including a first emitter and a second emitter;
a controller for controlling the first emitter and the second emitter to both emit light or not emit light simultaneously when the display unit operates in 2D display mode, and for controlling the first emitter and the second emitter to emit light alternately when the display unit operates in the 3D display mode; and
an emission driver for controlling power supply of the first emitter and the second emitter according to the control of the controller.
